(19) United States
(12) Patent Application Publication
(10) Pub. No.: US 2024/0320837 A1
(43) Pub. Date: Sep. 26, 2024

(54) POSITION DETECTION METHOD AND SUBSTRATE PROCESSING APPARATUS

(71) Applicant: Tokyo Electron Limited, Tokyo (JP)

(72) Inventors: Hikaru SATO, Iwate (JP); Yuta HAGA, Iwate (JP); Motoi OKADA, Hokkaido (JP); Kei SANO, Hokkaido (JP); Motohiro OKAYA, Hokkaido (JP)

(21) Appl. No.: 18/606,633

(22) Filed: Mar. 15, 2024

(30) Foreign Application Priority Data
Mar. 22, 2023 (JP) 2023-045844

(51) Int. Cl. G06T 7/13; G06T 7/73; H01L 21/67

(52) U.S. Cl. CPC G06T 7/13; G06T 7/73; H01L 21/67259; G06T 2207/20061; G06T 2207/30148

(57) ABSTRACT

A position detection method includes providing a substrate processing apparatus including a chamber having a first detection target portion, a susceptor having a second detection target portion and configured to be rotatable within the chamber, and an imaging device; acquiring an image captured by the imaging device; generating an edge detection image in which an edge is detected, from the image captured by the imaging device; and detecting positions of the first detection target portion and the second detection target portion from the edge detection image using Hough transformation.

### CROSS-REFERENCE TO RELATED APPLICATIONS

The present application is based on and claims priority from Japanese Patent Application No. 2023-045844, filed on Mar. 22, 2023, with the Japan Patent Office, the disclosure of which is incorporated herein in its entirety by reference.

### TECHNICAL FIELD

The present disclosure relates to a position detection method and a substrate processing apparatus.

### BACKGROUND

Japanese Patent Laid-open Publication No. 2012-094814 discloses a position detection method of detecting a substrate placement position, which is performed in a semiconductor manufacturing apparatus including a processing container in which a predetermined processing is performed on a substrate and a susceptor that is rotatably accommodated inside the processing container and is formed with a substrate stage on which the substrate, which is a position detection target, is placed. The position detection method includes moving the susceptor to position the substrate stage in an imaging area of an imaging device, detecting two first position detection marks provided inside the processing container so as to be positioned in the imaging area of the imaging device, a first vertical bisector of the two first position detection marks being provided to pass through the rotation center of the susceptor, detecting two second position detection marks provided on the susceptor with respect to the substrate stage, a second vertical bisector of the two second position detection marks being provided to pass through the rotation center of the susceptor and the center of the substrate stage, and determining whether the substrate stage is positioned within a predetermined range based on the detected two first position detection marks and two second position detection marks.

### SUMMARY

According to one aspect, there is provided a position detection method of detecting positions of a first detection target portion and a second detection target portion in a substrate processing apparatus including a chamber having the first detection target portion, a susceptor having the second detection target portion, the susceptor being rotatable within the chamber, and an imaging device, the method including acquiring an image captured by the imaging device, generating an edge detection image in which an edge is detected from the image captured by the imaging device, and detecting the positions of the first detection target portion and the second detection target portion from the edge detection image using Hough transformation.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional schematic diagram illustrating an example of a substrate processing apparatus according to an embodiment.

FIG. 2 is a plan view illustrating an example internal structure of a vacuum container in the substrate processing apparatus according to the embodiment.

FIG. 3 is a diagram illustrating an example of the principle of detecting the rotational position of a susceptor.

FIG. 4 is a flowchart illustrating an example of a control method for the substrate processing apparatus.

FIGS. 5A to 5C are cross-sectional schematic diagrams of the susceptor illustrating examples of a susceptor detection target portion.

FIG. 6 is a flowchart illustrating an example of a position detection method.

FIGS. 7A to 7C are examples of image data at each step.

### DETAILED DESCRIPTION

The foregoing summary is illustrative only and is not intended to be in any way limiting. In addition to the illustrative aspects, embodiments, and features described above, further aspects, embodiments, and features will become apparent by reference to the drawings and the following detailed description.

Hereinafter, embodiments for carrying out the present disclosure will be described with reference to the drawings. In each drawing, the same reference numerals may be given to the same components, and redundant descriptions may be omitted.

### [Substrate Processing Apparatus]

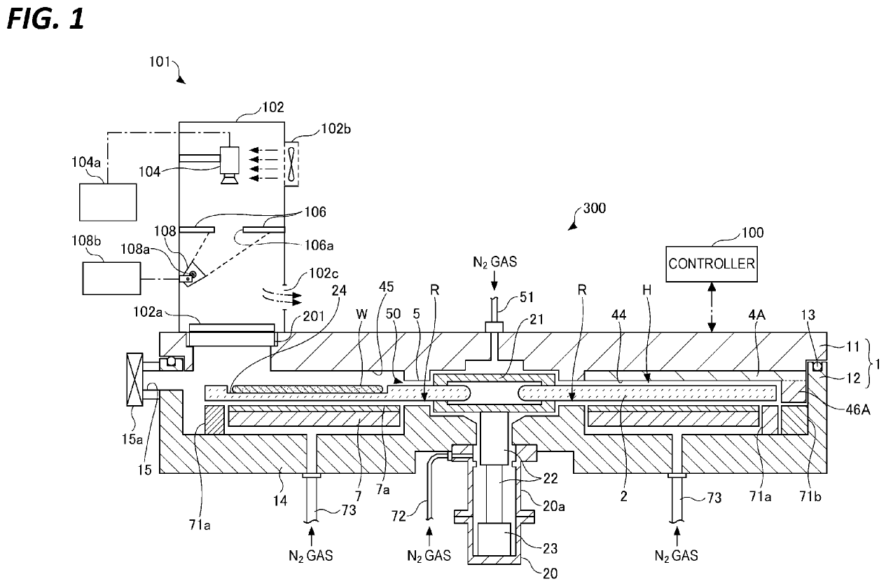

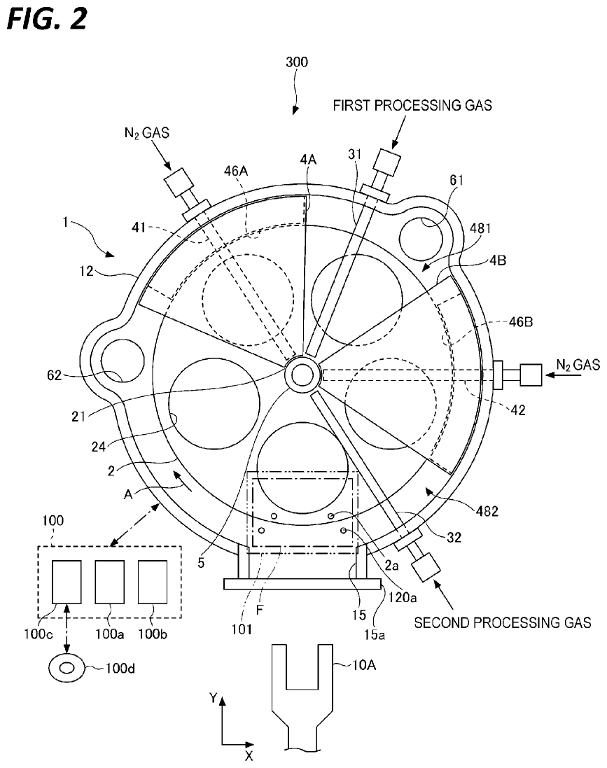

A substrate processing apparatus 300 according to an embodiment will be described with reference to FIGS. 1 and 2. FIG. 1 is a cross-sectional schematic diagram illustrating an example of the substrate processing apparatus 300 according to an embodiment. FIG. 2 is a plan view illustrating an example internal structure of a vacuum container 1 in the substrate processing apparatus 300 according to the embodiment.

The substrate processing apparatus 300 according to the present embodiment includes the vacuum container 1 and a susceptor 2 provided inside the vacuum container 1 and having a rotation center at the center of the vacuum container 1.

The vacuum container 1 includes a container body 12 having a bottomed cylindrical shape and a top plate 11 placed airtightly on an upper surface of the container body 12 via a sealing member 13 such as, for example, an O-ring. The top plate 11 and the container body 12 are made of metal such as, for example, aluminum (Al). The top plate 11 is provided airtightly with a light-transmissive window 201, which is made of, for example, quartz glass, via a sealing member (not illustrated) such as an O-ring. The light-transmissive window 201 is provided adjacent to a transfer port 15, which is opened in a sidewall of the container body 12. The transfer port 15 is provided for loading and unloading a wafer W into and from the vacuum container 1. A gate valve 15a is provided at the transfer port 15, which enables the opening or closing of the transfer port 15.

Further, the substrate processing apparatus 300 is provided with a position detection device 101. Specifically, the position detection device 101 is arranged above the light-transmissive window 201 provided in the top plate 11 of the substrate processing apparatus 300. Further, the position detection device 101 includes a housing 102, a camera 104 mounted inside the housing 102 to capture images of the wafer W, which is a position detection target, a panel 106 arranged below the camera 104 inside the housing 102, and a light source 108 that emits light to the panel 106.

The housing 102 has an opening at the bottom, and this opening is sealed by a transparent window 102a. The window 102a faces the light-transmissive window 201 of the top plate 11. Further, the housing 102 is provided with a cooling fan 102b at an upper portion of a sidewall thereof and an opening 102c at a lower portion of the sidewall. As indicated by the double-dot chain arrows in FIG. 1, the cooling fan 102b blows outside air to the camera 104, and discharges the outside air through the opening 102c, enabling the cooling of the camera 104. Further, when the wafer W is heated during position detection, the window 102a may be heated by radiant heat, which generates hot air flow inside the housing 102, potentially blurring the images. However, since the window 102a may also be cooled by the cooling fan 102b, blurring of the images due to hot air flow may be reduced.

The camera 104 has, for example, a charge-coupled device (CCD) as an imaging device and is mounted in an upper region of the housing 102 to face the window 102a. With this configuration, the camera 104 may capture images of the wafer W placed on the susceptor 2 inside the vacuum container 1 through the window 102a and the light-transmissive window 201 of the top plate 11 in the substrate processing apparatus 300. In particular, since the light-transmissive window 201 of the top plate 11 is formed at a position adjacent to the transfer port 15, it may capture images of the wafer W that is being loaded or unloaded through the transfer port 15. In other words, this allows for the prompt detection of the position of the wafer W during loading and unloading.

Further, a controller 104a is electrically connected to the camera 104. The controller 104a controls the operation (on/off, focusing, imaging, etc.) of the camera 104 and processes image data obtained by the camera 104. This processing includes a calculation processing to obtain the position of the wafer W or the susceptor 2 from the image data. Further, the controller 104a downloads a program stored in a storage medium through a predetermined input/output device (not illustrated) and controls each component such as the camera 104 or the light source 108 according to this program, thereby executing a substrate position detection method to be described later.

In the present embodiment, the panel 106 is made of a milky white acrylic plate coated with a white pigment and is mounted between the camera 104 and the window 102a inside the housing 102. An opening 106a is formed approximately in the center of the panel 106. Through the opening 106a, the wafer W and its surroundings inside the substrate processing apparatus 300 are imaged by the camera 104. Accordingly, the position and size of the opening 106a are determined to allow the camera 104 to capture images the wafer W and a surrounding area thereof inside the vacuum container 1. Specifically, as illustrated in FIG. 2, this determination may be made to secure the field of view F including an edge of the wafer W used for the detection of a wafer position, a susceptor detection target portion 2a (second detection target portion) formed on the susceptor 2, and a chamber detection target portion 120a (first detection target portion) formed on a bottom surface of the container body 12 of the substrate processing apparatus 300, and may be made in consideration of the distance between the panel 106 and the camera 104.

In the present embodiment, the light source 108 is mounted on an inner wall of the housing 102 between the panel 106 and the window 102a to emit light to a lower surface of the panel 106 and to prevent the light from reaching the camera 104 through the opening 106a. The light source 108 indirectly illuminates the wafer W and the susceptor 2 within the field of view F through the emission of light to the panel 106. The light source 108 may be mounted to be pivotable in the vertical direction, and moreover, may be particularly provided with a predetermined motor or the like to enable the switching of the light emitting direction. In this way, it is possible to selectively emit light to the panel 106 above the light source 108 or to the wafer W below the light source 108.

In the present embodiment, the light source 108 includes a white light emitting diode (LED) 108a and a power supply 108b that supplies power to the white LED 108a. The power supply 108b may vary an output voltage, allowing the adjustment of the illuminance to the wafer W, which is indirectly illuminated via the panel 106. By adjusting the illuminance, the camera 104 may capture clearer images.

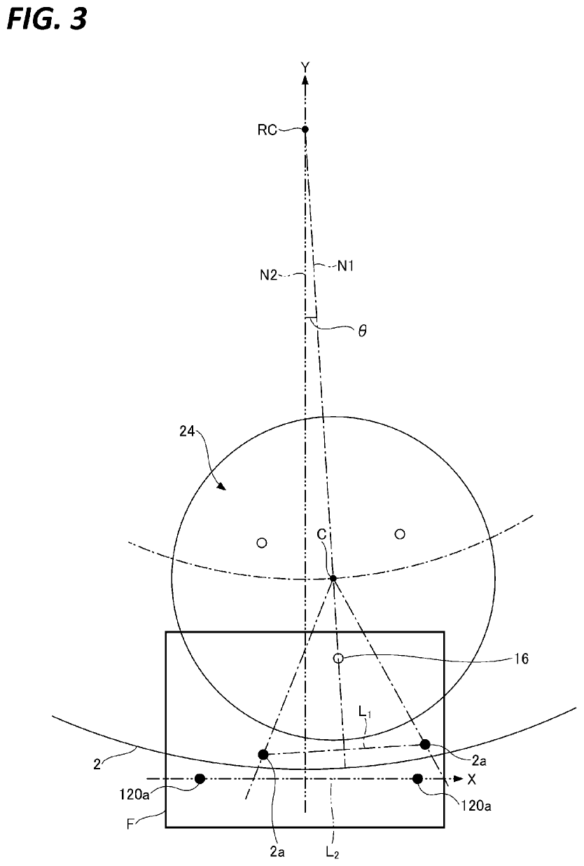

A plurality of stages 24 on which the wafer W is placed are formed on the susceptor 2 arranged inside the vacuum container 1. In the present embodiment, the stages 24 are configured as recesses. Specifically, for the wafer W having a diameter of about 300 mm (12 inches), the inner diameter of the stages 24 as recesses may range, for example, from about 304 mm to about 308 mm. Further, the stages 24 have a depth that is approximately equal to the thickness of the wafer. With the stages 24 configured in this way, when the wafer W is placed on the stage 24, a surface of the wafer W and a surface of the susceptor 2 (area where the stage 24 is not formed) are at the same height. In other words, since there is no step due to the thickness of the wafer W, disturbance in the flow of a gas on the susceptor 2 may be reduced. Further, three through-holes 16 (see FIG. 3 to be described later) are formed in each stage 24 of the susceptor 2, and vertically movable lift pins (not illustrated) are provided through the respective through-holes 16.

The susceptor 2 has a circular opening in the center, and a cylindrical core portion 21 is vertically fitted and held around the opening. The core portion 21 is fixed to a rotating shaft 22 at the bottom thereof, and the rotating shaft 22 is connected to a drive 23. The core portion 21 and the rotating shaft 22 have a common rotation axis, and the rotation of the drive 23 allows the rotating shaft 22, the core portion 21, and consequently, the susceptor 2 to rotate.

The rotating shaft 22 and the drive 23 are received inside a cylindrical case body 20 with an open upper surface. The case body 20 is airtightly mounted on the underside of the vacuum container 1 through a flange portion 20a provided on an upper surface thereof, ensuring that the internal atmosphere of the case body 20 is isolated from the external atmosphere.

Referring to FIG. 2, the vacuum container 1 is provided with two convex portions 4A and 4B spaced apart from each other above the susceptor 2. As illustrated, the convex portions 4A and 4B have a substantially fan-shaped upper surface. The fan-shaped convex portions 4A and 4B are arranged such that the apexes thereof are close to the outer periphery of a protrusion 5, which is mounted to the top plate 11 to surround the core portion 21, and the arcs thereof extend along an inner peripheral wall of the container body 12. In FIG. 2, the top plate 11 is omitted for convenience of explanation, but the convex portions 4A and 4B are mounted to a lower surface of the top plate 11 (the convex portion 4A is also illustrated in FIG. 1). The convex portions 4A and 4B may be made of metal such as, for example, aluminum.

Although not illustrated, the convex portion 4B is also arranged similarly to the convex portion 4A. Since the convex portion 4B has approximately the same configuration as the convex portion 4A, there may be cases where a redundant description about the convex portion 4A is omitted when the convex portion 4B is described.

The convex portion 4B has a groove (not illustrated) extending in the radial direction such that the convex portion 4B is divided into two, and a separation gas nozzle 42 is accommodated in the groove. As illustrated in FIG. 2, the separation gas nozzle 42 is introduced into the vacuum container 1 from a peripheral wall portion of the container body 12 and extends in the radial direction of the vacuum container 1. Further, the separation gas nozzle 42 has a base end mounted to an outer peripheral wall of the container body 12, thereby being supported substantially parallel to the surface of the susceptor 2. A separation gas nozzle 41 is similarly arranged on the convex portion 4A.

The separation gas nozzles 41 and 42 are connected to a source (not illustrated) for a separation gas. The separation gas may be a nitrogen (N₂) gas or any inert gas, and the type of separation gas is not particularly limited as long as it does not affect film formation. In the present embodiment, the N₂ gas is used as the separation gas. Further, the separation gas nozzle 42 has a discharge hole for discharging the N₂ gas toward the surface of the susceptor 2. A discharge hole is similarly formed in the separation gas nozzle 41.

A separation space H is formed by the susceptor 2 and the convex portion 4B. Meanwhile, a first area 481 and a second area 482 are defined at both sides of the convex portion 4B by the surface of the susceptor 2 and a lower surface 45 of the top plate 11. A processing gas nozzle 31 is provided in the first area 481, and a processing gas nozzle 32 is provided in the second area 482. The processing gas nozzles 31 and 32 are introduced into the vacuum container 1 from the outer peripheral wall of the container body 12 and extend in the radial direction of the vacuum container 1 as illustrated in FIG. 1. The processing gas nozzles 31 and 32 are formed with a plurality of discharge holes (not illustrated) that open downward. A first processing gas is supplied from the processing gas nozzle 31, and a second processing gas is supplied from the processing gas nozzle 32.

When supplying the N₂ gas from the separation gas nozzle 42, the N₂ gas flows from the separation space H toward the first area 481 and the second area 482. Since the height of the separation space H is lower than that of the first and second areas 481 and 482, it is easy to maintain a higher pressure in the separation space H than in the first and second areas 481 and 482. In other words, the height and width of the convex portion 4A and the supply amount of the N₂ gas from the separation gas nozzle 41 may be determined to maintain a higher pressure in the separation space H than in the first and second areas 481 and 482. For this determination, it is more desirable to consider the first and second processing gases, the rotational speed of the susceptor 2, etc. In this way, the separation space H may provide a pressure barrier to the first and second areas 481 and 482, ensuring reliable separation between the first and second areas 481 and 482.

In other words, even when the first processing gas is supplied from the processing gas nozzle 31 to the first area 481 and flows toward the convex portion 4B by the rotation of the susceptor 2, it may not escape the separation space H to reach the second area 482 due to the pressure barrier formed in the separation space H. The second processing gas supplied from the processing gas nozzle 32 to the second area 482 is also prevented from escaping the separation space H to reach the first area 481 due to the pressure barrier formed in the separation space H below the convex portion 4B (FIG. 1). In other words, the mixing of the first and second processing gases through the separation space H may be effectively prevented.

Referring again to FIG. 1, the protrusion 5 is mounted on the lower surface of the top plate 11 to surround the core portion 21 that fixes the susceptor 2. The protrusion 5 is close to the surface of the susceptor 2, and in the illustrated example, a lower surface of the protrusion 5 is at approximately the same height as a lower surface 44 of the convex portion 4A(4B).

Meanwhile, a separation gas supply pipe 51 is connected to the upper center of the top plate 11, allowing the supply of the N₂ gas. With the N₂ gas supplied from the separation gas supply pipe 51, the space between the core portion 21 and the top plate 11, the space between the outer periphery of the core portion 21 and the inner periphery of the protrusion 5, and the space between the protrusion 5 and the susceptor 2 (hereinafter, for convenience of explanation, these spaces may be referred to as a central space 50) may have a higher pressure than in the first and second areas 481 and 482. In other words, the central space 50 may provide a pressure barrier to the first and second areas 481 and 482, ensuring reliable separation between the first and second areas 481 and 482. In other words, the mixing of the first and second processing gases through the central space 50 may be effectively prevented.

As illustrated in FIG. 1, an annular heater unit 7 serving as a heating device is provided in the space between the susceptor 2 and the bottom of the container body 12, allowing the wafer W on the susceptor 2 to be heated to a predetermined temperature through the susceptor 2. Further, a block member 71a is provided below and near the outer periphery of the susceptor 2 to surround the heater unit 7. This causes the space where the heater unit 7 is located to be partitioned from the area outside the heater unit 7. To prevent any gas from flowing inside the block member 71a, a slight gap is maintained between an upper surface of the block member 71a and a lower surface of the susceptor 2. To purge the area where the heater unit 7 is accommodated, a plurality of purge gas supply pipes 73 are connected to this area to penetrate the bottom of the container body 12. The plurality of purge gas supply pipes 73 may be arranged at a predetermined interval, for example, at an equiangular interval in the bottom of the container body 12. A protective plate 7a is arranged above the heater unit 7 to protect the heater unit 7. This ensures that even when the processing gas is inadvertently introduced into the space where the heater unit 7 is provided, the heater unit 7 may be protected. The protective plate 7a may be made of, for example, quartz.

The heater unit 7 may be composed of a plurality of lamp heaters arranged, for example, in a concentric circle shape. This allows for the independent control of each lamp heater, achieving a uniform temperature of the susceptor 2.

Referring to FIG. 1, the bottom of the container body 12 has a raised portion R inside the annular heater unit 7. An upper surface of the raised portion R is close to the susceptor 2 and the core portion 21, leaving a slight gap between the upper surface of the raised portion R and the underside of the susceptor 2 as well as between the upper surface of the raised portion R and the underside of the core portion 21. Further, the bottom of the container body 12 has a central hole through which the rotating shaft 22 passes. The inner diameter of this central hole is slightly larger than the diameter of the rotating shaft 22, leaving a gap that communicates with the case body 20 through the flange portion 20a. A purge gas supply pipe 72 is connected to the top of the flange portion 20a of the case body 20.

With this configuration, the N₂ gas flows from the purge gas supply pipe 72 to the space below the heater unit 7 through the gap between the rotating shaft 22 and the central hole in the bottom of the container body 12, the gap between the core portion 21 and the raised portion R below the susceptor 2, and the gap between the raised portion R and the underside of the susceptor 2. Further, the N₂ gas flows from the purge gas supply pipes 73 to the space below the heater unit 7. Then, the N₂ gas flows to an exhaust port 61(62) to be described later through the gap between the block member 71a and the underside of the susceptor 2. The N₂ gas flowing in this way acts as a separation gas that prevents a reaction gas, which is one processing gas, from recirculating in the space below the susceptor 2 and mixing with the other processing gas.

Further, as illustrated in FIG. 2, in the space between an inner peripheral surface of the container body 12 and an outer peripheral edge of the susceptor 2, a bent portion 46A is provided at a position corresponding to the bottom of the convex portion 4A and a bent portion 46B is provided at a position corresponding to the bottom of the convex portion 4B. Since the bent portions 46A and 46B have the same configuration, the description will focus on the bent portion 46A with reference to FIGS. 1 and 2. As illustrated, in the present embodiment, the bent portion 46A is formed integrally with the convex portion 4A. The bent portion 46A substantially fills the space between the susceptor 2 and the container body 12, preventing the first processing gas from the processing gas nozzle 31 from mixing with the second processing gas through this space. The gap between the bent portion 46A and the container body 12 and the gap between the bent portion 46A and the susceptor 2 may have approximately the same height from the susceptor 2 to the lower surface 44 of the convex portion 4A. Further, due to the presence of the bent portion 46A, it is difficult for the N₂ gas from the separation gas nozzle 41 to flow outward of the susceptor 2 (FIG. 1). Accordingly, it is helpful to maintain a higher pressure in the separation space H (space between the lower surface 44 of the convex portion 4A and the susceptor 2). In the illustrated example, it is more desirable that the block member 71b is provided below the bent portion 46A, further aiding in preventing the flow of the separation gas below the susceptor 2.

Further, as illustrated in FIG. 2, in the first area 481, a portion of the container body 12 expands outward, and the exhaust port 61 is formed below the expanded portion. Similarly, in the second area 482, a portion of the container body 12 expands outward, and the exhaust port 62 is formed below the expanded portion. The exhaust ports 61 and 62 are separately or commonly connected to an exhaust system (not illustrated), which includes, for example, a pressure regulator and a turbomolecular pump, enabling the adjustment of the pressure inside the vacuum container 1. Since the exhaust ports 61 and 62 are formed respectively for the first area 481 and the second area 482, the first and second areas 481 and 482 are mainly exhausted. Accordingly, as described above, it becomes possible to maintain a lower pressure in the first and second areas 481 and 482 than in the separation space H. Further, the exhaust port 61 is provided between the processing gas nozzle 31 and the convex portion 4B located downstream of the processing gas nozzle 31 along the rotation direction A of the susceptor 2. Further, the exhaust port 62 is provided close to the convex portion 4A between the processing gas nozzle 32 and the convex portion 4A located downstream of the processing gas nozzle 32 along the rotation direction A of the susceptor 2. This ensures that the first processing gas supplied from the processing gas nozzle 31 is discharged only from the exhaust port 61 and the second processing gas supplied from the processing gas nozzle 32 is discharged only from the exhaust port 62. In other words, this arrangement of the exhaust ports 61 and 62 contributes to the separation of both reaction gases.

Further, as illustrated in FIG. 2, the substrate processing apparatus 300 according to this embodiment is provided with a controller 100 for controlling the operation of the entire apparatus. The controller 100 includes a process controller 100a configured with, for example, a computer, a user interface 100b, and a memory device 100c. The user interface 100b includes a display that displays the operating status of a film forming apparatus and an input device such as a keyboard or touch panel (not illustrated) that allows an operator of the film forming apparatus to select a process recipe or that allows a process manager to change parameters of the process recipe.

The memory device 100c stores control programs, process recipes, parameters for various processes, and others that cause the process controller 100a to execute various processes. Further, these programs may include a group of steps, for example, for performing a film forming method to be described later. The control programs and process recipes are read by the process controller 100a and are executed by the controller 100 in response to an instruction from the user interface 100b. Further, these programs may be stored in a computer-readable storage medium 100d and may be installed in the memory device 100c through an input/output device (not illustrated) corresponding thereto. The computer-readable storage medium 100d may be a hard disk, CD, CD-R/RW, DVD-R/RW, flexible disk, semiconductor memory, etc. Further, the programs may be downloaded to the memory device 100c through a communication line.

### [Control Method of Substrate Processing Apparatus]

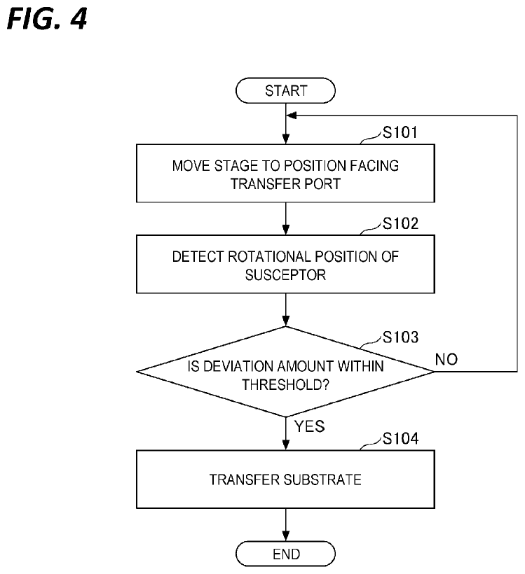

Next, an example of a control method for the substrate processing apparatus 300 will be described with reference to FIGS. 3 and 4. FIG. 3 is a diagram illustrating an example of the principle of detecting the rotational position of the susceptor 2. FIG. 4 is a flowchart illustrating an example of a control method for the substrate processing apparatus 300. Here, a case where the wafer W is transferred to one of the plurality of stages 24 will be described by way of example.

In step S101, the controller 100 controls the drive 23 to rotate the susceptor 2, moving one of the plurality of stages 24 to a position facing the transfer port 15 (see FIG. 2). Here, the stage 24 on which the wafer W is placed is moved to the position facing the transfer port 15 (see FIG. 2).

In step S102, the controller 100 uses the position detection device 101 to detect the rotational position of the susceptor 2. In other words, the controller 100 uses the position detection device 101 to detect the position of the stage 24 moved to the position facing the transfer port 15.

Specifically, first, the light source 108 of the position detection device 101 is turned on to emit light to the lower surface of the panel 106. Then, the camera 104 of the position detection device 101 captures images of the area including the edge of the susceptor 2, which is indirectly illuminated by the panel 106, and the controller 104a collects image data. Here, the image data of the field of view F illustrated in FIG. 3 is collected. The image data includes captured images of two susceptor detection target portions 2a formed on the susceptor 2 and two chamber detection target portions 120a formed on the bottom of the container body 12 of the vacuum container 1.

Here, as illustrated in FIG. 3, the two susceptor detection target portions 2a are arranged symmetrically with respect to a straight line passing through the center C of the stage 24 and the rotation center RC of the susceptor 2. In other words, when a vertical line N1 is drawn from the rotation center RC of the susceptor 2 to a line segment L₁ connecting the centers of the two susceptor detection target portions 2a, this vertical line N1 passes through the center C of the stage 24 and intersects the midpoint of the line segment L₁. In other words, the vertical line N1 is a vertical bisector of the line segment L₁. Further, the vertical line N1 is the centerline (susceptor centerline) of one stage 24 of the susceptor 2.

Further, when a vertical line N₂ is drawn from the rotation center RC of the susceptor 2 to a line segment L₂ connecting the centers of the two chamber detection target portions 120a, this vertical line N₂ intersects the midpoint of the line segment L₂. In other words, the vertical line N₂ is a vertical bisector of the line segment L₂. Further, the vertical line N₂ is the chamber centerline.

Further, an angle θ between the vertical line N1 and the vertical line N₂ is a deviation amount of the susceptor 2.

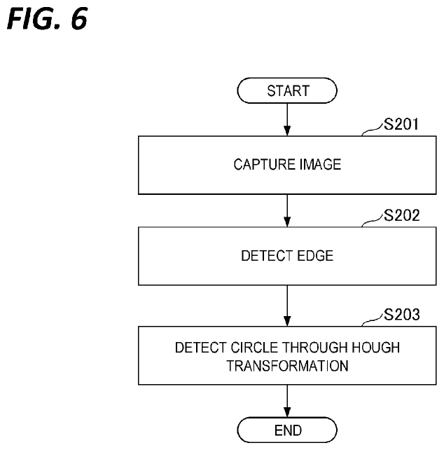

The controller 104a detects the positions of the two susceptor detection target portions 2a and the two chamber detection target portions 120a by a detection method to be described later with reference to FIG. 6. Specifically, it detects the circular shape (center position and radius of a circle) of the two susceptor detection target portions 2a and the two chamber detection target portions 120a.

Then, the controller 104a determines the angle θ between the vertical line N1 (susceptor centerline) and the vertical line N₂ (chamber centerline) based on the positions of the two susceptor detection target portions 2a and the two chamber detection target portions 120a. Further, the controller 104a calculates the position of the center C of the stage 24 based on the detected angle θ.

In step S103, the controller 100 determines whether the deviation amount in the rotational position of the susceptor 2 is within a threshold. When the deviation amount is not within the threshold (NO in S103), the processing of the controller 100 returns to step S101, adjusting the position of the susceptor 2 again. At this time, it may rotate the susceptor 2 based on the angle θ detected in step S102. When the deviation amount is within the threshold (YES in S103), the processing of the controller 100 proceeds to step S104.

In step S104, the controller 100 controls a transfer arm to transfer the wafer W. Here, the controller 100 adjusts the insertion position of a pick 10A of the transfer arm based on the position of the center C of the stage 24 calculated in step S102. This allows the position alignment of the center C of the stage 24 with the center position of the wafer W supported by the pick 10A. Further, since the deviation amount in the rotational position of the susceptor 2 may be within the threshold, it ensures that the lift pins do not contact with the susceptor 2 around the through-holes 16 when raised from the through-holes 16.

Although the processing of transferring the wafer W to the stage 24 has been described by way of example, the present disclosure is not limited thereto. The same is applied when unloading the wafer W from the stage 24.

### [Susceptor Detection Target Portion]

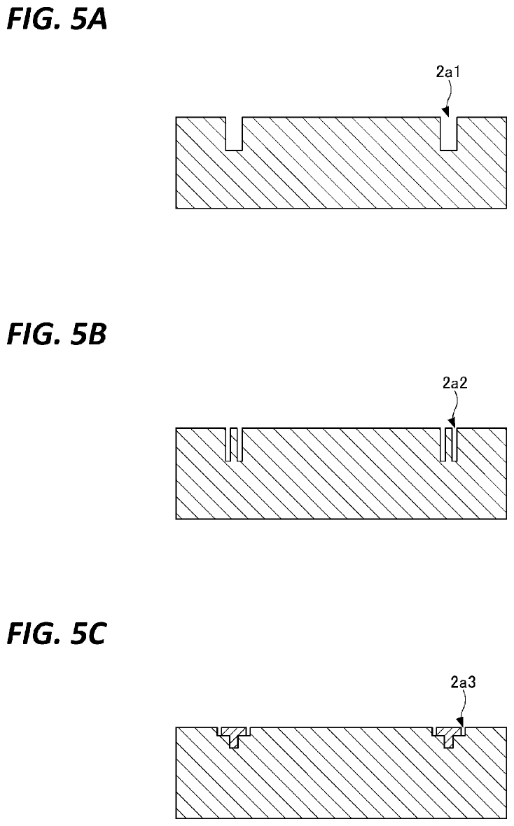

Here, an example of the susceptor detection target portion 2a will be described with reference to FIGS. 5A to 5C. FIGS. 5A to 5C are cross-sectional schematic diagrams of the susceptor 2 illustrating examples of the susceptor detection target portion 2a (2a1 to 2a3).

The susceptor detection target portion 2a1 illustrated in FIG. 5A is a recess formed on an upper surface of the susceptor 2 and is formed in a circular shape in plan view (see FIGS. 2 and 3).

The susceptor detection target portion 2a2 illustrated in FIG. 5B is a recess formed on the upper surface of the susceptor 2 and is formed in an annular shape in plan view.

The susceptor detection target portion 2a3 illustrated in FIG. 5C is a disc-shaped member arranged in a recess formed on the susceptor 2. The disc-shaped member may have a different color from the susceptor 2.

Further, the chamber detection target portion 120a may be a disk-shaped member arranged in a recess formed on the bottom of the container body 12, similar to the susceptor detection target portion 2a3 illustrated in FIG. 5C. The chamber detection target portion 120a may be a circular recess in plan view, similar to the susceptor detection target portion 2a1 illustrated in FIG. 5A, or may be an annular recess in plan view, similar to the susceptor detection target portion 2a2 illustrated in FIG. 5B.

### [Detection Method of Susceptor Detection Target Portion]

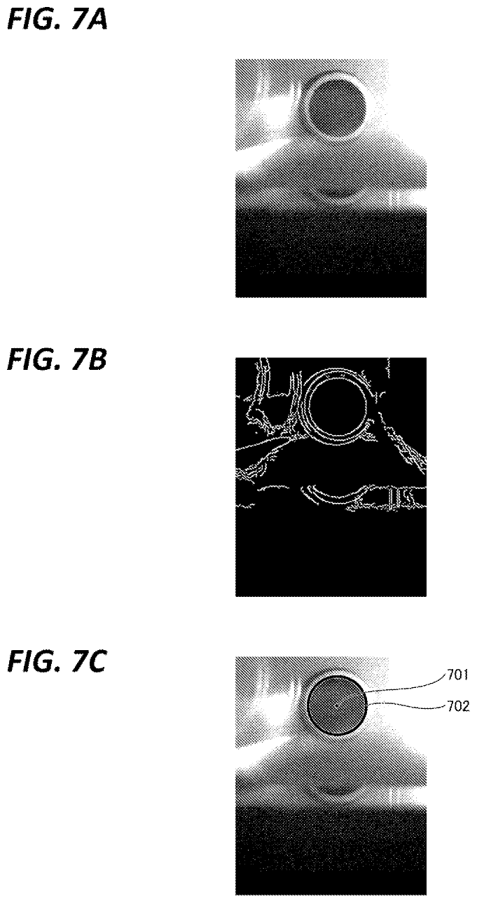

Next, a detection method of detecting the positions of the susceptor detection target portion 2a and the chamber detection target portion 120a will be described with reference to FIGS. 6 and 7A to 7C. FIG. 6 is a flowchart illustrating an example of a position detection method. FIGS. 7A to 7C are examples of image data at each step.

In step S201, the controller 104a captures images of the field of view F (see FIG. 3) with the camera 104 and acquires the captured image data. Here, the captured image data includes the two susceptor detection target portions 2a formed on the susceptor 2 and the two chamber detection target portions 120a formed on the bottom of the container body 12 of the vacuum container 1.

FIG. 7A is an example of an image in the vicinity of one susceptor detection target portion 2a of the image data captured in step S201. Here, a case where the disc-shaped member with a different color from the susceptor as illustrated in FIG. 5C is used as the susceptor detection target portion 2a will be described by way of example. In this example, the captured image includes the susceptor detection target portion 2a and the susceptor 2 around the susceptor detection target portion 2a.

In step S202, the controller 104a performs an edge detection processing on the image data acquired in step S201. Here, brightness variations are detected from the image data acquired in step S201 to detect an edge, resulting in the generation of an edge detection image.

FIG. 7B is an example of the edge detection image processed in step S202. Here, an image processing is performed such that areas with brightness variations greater than or equal to a threshold appear in white, while areas with brightness variations below the threshold appear in black.

In step S203, the controller 104a performs a processing to detect a circle from the edge detection image by Hough transformation. Here, Hough transformation is applied to each edge in the edge detection image processed in step S202 to extract a circle from the edge detection image. Then, the controller 104a acquires the center coordinates and radius of the extracted circle.

FIG. 7C is an example where a circle 702 and a circle center 701 detected in step S203 are superimposed and displayed on the captured image.

Here, while a case where the position (center position of the detected circle) is detected for one susceptor detection target portion 2a has been described by way of example, similarly, Hough transformation is applied to detect a circle and the position thereof for the other susceptor detection target portion 2a and the two chamber detection target portions 120a.

In this way, with the position detection method illustrated in FIG. 6, the controller 100 may use Hough transformation to detect the positions of the two susceptor detection target portions 2a and the two chamber detection target portions 120a from the captured image. Then, the controller 100 may detect the angle θ of the susceptor 2 based on the detected positions of the two susceptor detection target portions 2a and the two chamber detection target portions 120a (see FIGS. 3 and S102 of FIG. 4). Further, the controller 100 may detect the center C of the stage 24 based on the detected angle θ of the susceptor 2 (see FIG. 3).

Here, when processing the substrate, the susceptor 2 rotates. This allows the vicinity of the susceptor detection target portion 2a to alternately pass through the first and second areas 481 and 482. Consequently, a film is formed on the upper surface of the susceptor 2 (including an upper surface of the susceptor detection target portion 2a and the upper surface of the susceptor 2 around the susceptor detection target portion 2a) due to reaction products during substrate processing. This may potentially lead to a reduction in contrast between the susceptor detection target portion 2a and the upper surface of the susceptor 2 around the susceptor detection target portion 2a in the image captured by the camera 104.

Further, by repeating the substrate processing, the reaction products from the substrate processing may adhere to a lower surface of the light-transmissive window 201, causing a risk of dirt on the light-transmissive window 201. The reaction products adhered to the lower surface of the light-transmissive window 201 may cause light from the light source 108 to be reflected, leading to the possibility of noise due to reflection in the image captured by the camera 104.

In contrast, according to the position detection method illustrated in FIG. 6, even in a case where the contrast between the susceptor detection target portion 2a and the upper surface of the susceptor 2 around the susceptor detection target portion 2a is reduced, or where the light from the light source 108 is reflected by the light-transmissive window 201, the circular shape of the susceptor detection target portion 2a and the chamber detection target portion 120a may be appropriately detected. This contributes to improving the accuracy of detecting the positions of the susceptor detection target portion 2a and the chamber detection target portion 120a. Further, by improving the detection accuracy, it is possible to reduce the need for re-detection processing, thereby shortening the detection time.

Further, with the position detection method illustrated in FIG. 6, it is possible to detect a recess shape (see FIGS. 5A and 5B) as the susceptor detection target portion 2a. By forming the susceptor detection target portion 2a into a recess shape, it becomes possible to accurately detect the circular shape of the susceptor detection target portion 2a even when a film is formed on the surface of the susceptor 2 due to reaction products. Further, compared to a configuration in which the disc-shaped member is arranged in the recess illustrated in FIG. 5C, there is no need for the replacement of the disc-shaped member. This may reduce the maintenance cost of the substrate processing apparatus 300 and may shorten the maintenance work time.

The description has been focused on the susceptor detection target portion 2a and the chamber detection target portion 120a having a circular shape in plan view and the circle detected by Hough transformation in step S203, but is not limited thereto. The susceptor detection target portion 2a and the chamber detection target portion 120a may have a polygonal shape formed by a plurality of straight lines in plan view. In this case, it is permissible to detect the straight lines by Hough transformation in step S203 and to detect the position of the polygonal shape based on the detected straight lines.

According to one aspect, it is possible to provide a position detection method and a substrate processing apparatus for detecting the position of a detection target portion provided in a chamber and a susceptor.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A position detection method comprising:
providing a substrate processing apparatus including a chamber having a first detection target portion, a susceptor having a second detection target portion and configured to be rotatable within the chamber, and an imaging device;
acquiring an image captured by the imaging device;
generating an edge detection image in which an edge is detected, from the image captured by the imaging device; and
detecting positions of the first detection target portion and the second detection target portion from the edge detection image using Hough transformation.

2. The position detection method according to claim 1, wherein the generating the edge detection image includes detecting the edge from a brightness variation.

3. The position detection method according to claim 1, wherein the second detection target portion is a recess formed on the susceptor.

4. The position detection method according to claim 3, wherein the second detection target portion is a circular recess.

5. The position detection method according to claim 3, wherein the second detection target portion is an annular recess.

6. The position detection method according to claim 1, wherein the second detection target portion is a disc-shaped member arranged in a recess formed on the susceptor.

7. The position detection method according to claim 1, wherein the first detection target portion and the second detection target portion have a circular shape in plan view, and
wherein the Hough transformation detects the circular shape.

8. The position detection method according to claim 1, wherein the first detection target portion and the second detection target portion have a polygonal shape with a plurality of straight lines in plan view, and
wherein the Hough transformation detects the straight lines.

9. A substrate processing apparatus comprising:
a chamber having a first detection target portion;
a susceptor having a second detection target portion, the susceptor being rotatable within the chamber;
an imaging device; and
a controller,
wherein the controller is configured to execute a process including:
acquiring an image captured by the imaging device;
generating an edge detection image in which an edge is detected, from the image captured by the imaging device; and
detecting positions of the first detection target portion and the second detection target portion from the edge detection image using Hough transformation.
